(19) United States
(12) Patent Application Publication
(10) Pub. No.: US 2008/0181008 A1
(43) Pub. Date: Jul. 31, 2008

(54) FLASH MEMORY SYSTEM CAPABLE OF IMPROVING ACCESS PERFORMANCE AND ACCESS METHOD THEREOF

(76) Inventors: Byeong-Hoon Lee, Seoul (KR); Ki-Hong Kim, Suwon-si (KR); Seung-Won Lee, Seongnam-si (KR); Sun-Kwon Kim, Suwon-si (KR)

Correspondence Address: F. CHAU & ASSOCIATES, LLC, 130 WOODBURY ROAD, WOODBURY, NY, 11797, US

(21) Appl. No.: 11/693,106

(22) Filed: Mar. 29, 2007

(30) Foreign Application Priority Data
Jan. 25, 2007 (KR) 2007-08025

(51) Int. Cl. G11C 11/34

(52) U.S. Cl. 365/185.17; 365/185.18; 365/185.22; 365/185.33

(57) ABSTRACT

A flash memory system capable of improving an access performance and an access method thereof. The system includes: a flash memory device including a plurality of storage regions; a contents memory storing setting information corresponding to the plurality of storage regions, respectively; and a processing unit setting operation conditions of the flash memory device by referring to the setting information during an access operation for the flash memory device.

### CROSS-REFERENCE TO RELATED APPLICATION

This application claims priority under 35 U.S.C. §119 of Korean Patent Application No. 2007-08025, filed on Jan. 25, 2007, the entire contents of which are hereby incorporated by reference.

### BACKGROUND OF THE INVENTION

The present disclosure relates to a semiconductor device and, more particularly, to an embedded flash memory system and an operating method thereof.

The latest mobile devices are light and thin for portability and are currently undergoing further development. Additionally, a semiconductor chip used in a smart card or an RFID tag needs to perform various functions and be constructed as one chip. In semiconductor chips used in portable terminals or smart cards, system-on-chip (SoC) technology is adopted for embodying a CPU, a DSP, and a memory in one chip. A memory mounted on a SoC in a portable terminal includes a DRAM, a SRAM, and a non-volatile memory such as a flash memory. A volatile semiconductor memory device has a fast read and write speed, but its stored data disappears when no power is applied. On the other hand, the non-volatile memory retains its stored data even when no power is applied. Therefore, the non-volatile memory is used to store data (for example, boot code) that need to remain regardless of the presence of a power supply. The flash memory mounted on the SoC is frequently formed of a fast NOR flash memory. The NOR flash memory has a fast operation property, but has a relatively small degree of integration.

Due to the trend toward light and thin devices, the high degree of integration is increasingly demanded in a mobile device and a smart card. In the case of a smart card, research has been actively under development to satisfy the need for fast data writing and reading operations and the need for high-capacity data storage. One solution for satisfying the need for fast data writing and reading operations is that the NAND flash memory is embedded into a chip of the smart card. Hereinafter, this NAND flash memory is referred to as an embedded NAND flash.

The NAND flash memory device injects electrons to a floating gate by F-N tunneling. On the other hand, the NOR flash memory injects electrons to a floating gate by hot electron injection. Program and read operations of the NAND flash memory are relatively slow. The reason for this is that the load of a control operation for program and read operations is large because the cell size of the NAND flash memory is relatively small and is highly integrated. More specifically, the embedded NAND flash memory biases a bulk region into negative high voltage during a program operation. Accordingly, the program operation of the embedded NAND flash needs to consider the time consumed for the high voltage set-up.

FIGS. 1A and 1B are graphs illustrating program characteristics of the NAND flash memory. Referring to FIG. 1A, each of distributions 10, 20, and 30 illustrates a threshold voltage distribution of memory cells in one programmed memory chip under the same conditions. More specifically, FIG. 1A illustrates the deviation of threshold voltage between respectively different pages when the same data are programmed under the same program conditions. Distribution 10 represents the threshold voltages of the memory cells in a page x. Distribution 20 represents the threshold voltages of the memory cells in a page y. Distribution 30 represents the threshold voltages of the memory cells in a page z. The deviation of the threshold voltage distribution between the pages of the NAND flash memory means there is a program speed difference between the pages. When the memory cells are programmed under the same conditions, the pages may need respectively different numbers of program loops. When the same program voltage and program time are applied, the threshold voltage of the memory cells in the same chip forms a broad distribution.

Referring to FIG. 1B, each of distributions 40, 50, and 60 illustrates a threshold voltage distribution of memory cells in one programmed memory chip under the same conditions. Distributions 40, 50, and 60 represent threshold voltage distributions of memory cells in blocks Block l, Block m, Block n, respectively.

Referring to FIGS. 1A and 1B, although the memory cells are in one memory chip, they have respectively different program speeds. The characteristics of the memory cells deteriorate the program speed in the NAND flash memory that is programmed under the same conditions.

FIGS. 2A, 2B, and 2C are graphs illustrating an erase state and a program state of the memory cells in one chip. FIG. 2A illustrates a threshold voltage distribution 70 corresponding to an erase state of the entire memory cells in one memory chip and a threshold voltage distribution 75 corresponding to a program state. The threshold voltage distributions 70 and 75 are spaced apart from each other by an interval ΔV1. A read voltage Vrd for reading data is set to a value between a threshold voltage V0 for the erased state and a threshold voltage V1 for the program state.

FIG. 2B illustrates a threshold voltage distribution 80 corresponding to an erase state of memory cells in one page, Page m, and a threshold voltage distribution 85 corresponding to a program state. The threshold voltage distributions 80 and 85 are spaced apart from each other by an interval ΔV2. FIG. 2C illustrates a threshold voltage distribution 90 corresponding to an erase state of another page, Page n, in one memory chip and a threshold voltage distribution 95 corresponding to a program state. The threshold voltage distributions 90 and 95 are spaced apart from each other by an interval ΔV3.

The deviation of the threshold voltage distribution between the pages may operate as a reliability defect in the flash memory device that is read by one read voltage Vrd. That is, due to a charge loss of floating data caused by deterioration or by hot temperature stress (HTS), a read margin of the flash memory may be reduced.

The characteristic difference (the deviation of the threshold voltage distribution) is described above by a page unit. Nevertheless, the characteristic difference between the memory cells may occur on a block unit basis. According to the program speed difference, the memory cells may have respectively different distributions of threshold voltages. The characteristic difference at each block unit may occur in the threshold voltage distribution corresponding to erase state. That is, the blocks may have respectively different erase characteristics when using a standardized erase voltage.

The deviation of the threshold voltage distribution occurring between pages or blocks decreases a program speed and a read margin in the flash memory device Accordingly, a device capable of improving high speed operation and high reliability is highly desirable in the flash memory system, especially, the embedded NAND flash memory.

### SUMMARY OF THE INVENTION

Exemplary embodiments of the present invention provide a system including a flash memory for access by considering the threshold voltage distribution of the memory cells in a minimum accessible unit.

Exemplary embodiments of the present invention also provide a flash memory capable of improving high speed operation and reliability by taking into consideration the deviation of threshold voltage distribution occurring between the memory cells.

Exemplary embodiments of the of the present invention provide systems including: a flash memory device including a plurality of storage regions; a contents memory storing setting information corresponding to the plurality of storage regions, respectively; and a processing unit setting operation conditions of the flash memory device by referring to the setting information during an access operation for the flash memory device.

In some exemplary embodiments, the flash memory device is a NAND flash memory.

In other exemplary embodiments, the plurality of storage regions is in a page unit.

In still other exemplary embodiments, the setting information includes one of a program parameter, an erase parameter, and a read parameter for one page unit.

In exemplary embodiments, the program parameter includes one of information such as a program start voltage, a step width, and a level of a program voltage, and the number of program loops is for one page unit.

According to exemplary embodiments, the erase parameter includes the size of a bulk voltage that is applied when an erase operation is performed.

In accordance with exemplary embodiments, the read parameter includes the size of a word line voltage that is applied when a read operation is performed.

In exemplary embodiments, the contents memory is a non-volatile memory.

According to exemplary embodiments, the processing unit detects a mode of the access operation and reads the setting information corresponding to the detected mode from the contents memory.

In exemplary embodiments, the processing unit performs a control operation for performing one of a read operation and a write operation by referring to the setting information.

In accordance with exemplary embodiments, the processing unit updates the setting information in the contents memory after the access operation.

According to exemplary embodiments, the system further includes a control register temporarily storing the setting information read from the contents memory.

In exemplary embodiments, the setting information are parameters corresponding to at least one storage region in the plurality of storage regions, the at least one storage region being accessed during the access operation.

According to exemplary embodiments, the flash memory device, the contents memory, and the processing unit are embedded devices and are embedded on a single chip.

In accordance with exemplary embodiments of the present invention, access methods of a flash memory device including a plurality of storage regions are provided, in which the access methods include: detecting an access mode; reading setting information corresponding to the access mode; and setting operation conditions of the flash memory device according to the setting information.

In exemplary embodiments, the access mode is a program operation mode writing data into the flash memory device.

In accordance with exemplary embodiments, the setting information corresponding to the program operation mode includes at least one of information such as a program start voltage, the step size of a program pulse, the number of program loops, and a size of a verify voltage.

In exemplary embodiments, the access mode is a read operation mode reading data programmed in the flash memory device.

In other exemplary embodiments, the setting information corresponding to the read operation mode includes information of a voltage supplied to a selected word line during the reading of the programmed data.

According to exemplary embodiments, the access mode is an erase operation mode erasing data programmed in the flash memory device.

In accordance with exemplary embodiments, the setting information corresponding to the erase operation mode includes at least one of bulk voltage information applied during the erase operation and size information of a word line voltage.

In exemplary embodiments, the method further includes accessing the flash memory device according to the access mode when the setting of the operation conditions is completed in the flash memory device.

According to exemplary embodiments, the method further includes updating the setting information according to an access operation.

In exemplary embodiments, the method further includes updating the setting information according to an access operation.

In accordance with exemplary embodiments, the flash memory device is a NAND flash memory.

In further exemplary embodiments, the plurality of storage regions corresponds to a page unit.

In exemplary embodiments, the plurality of storage regions corresponds to a block unit.

In further exemplary embodiments, the flash memory device is an embedded NAND flash memory device.

According to exemplary embodiments of the present invention, systems include: a flash memory device including a plurality of storage regions; a processing unit setting operation conditions of the flash memory device by referring to the setting information corresponding to the respective plurality of storage regions during an access operation for the flash memory device.

In exemplary embodiments, the setting information corresponding to the plurality of storage regions is stored in the contents memory.

According to the structures and methods of exemplary embodiments of the present invention, the present invention provides a system or an embedded system capable of improving speed for accessing a flash memory device and improving the reliability for read data.

### BRIEF DESCRIPTION OF THE FIGURES

Exemplary embodiments of the present invention, will be understood in more detail from the following descriptions taken in conjunction with the accompanying drawings. The drawings illustrate exemplary embodiments of the present invention and, together with the description, serve to explain principles of the present invention. In the figures:

FIG. 1A is a graph illustrating a threshold voltage distribution of memory cells of a page unit in a conventional NAND flash memory;

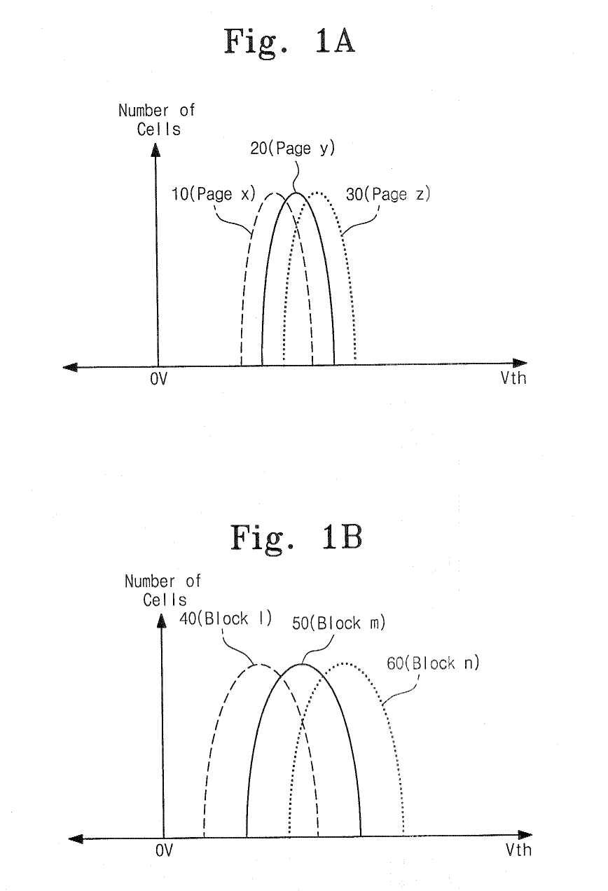

FIG. 1B is a graph illustrating a threshold voltage distribution of memory cells of a block unit in a conventional NAND flash memory;

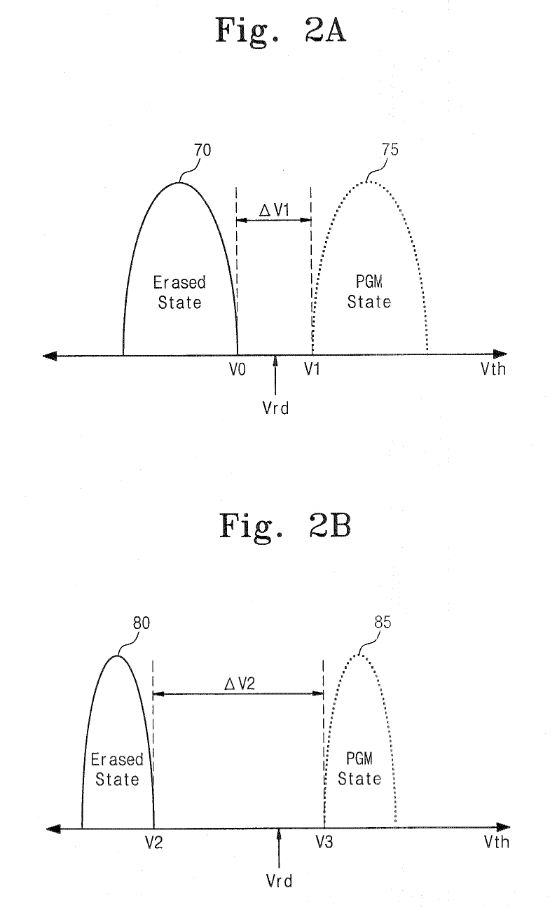

FIGS. 2A, 2B, and 2C are graphs illustrating deviations of threshold voltage distributions and conditions of read voltages between pages;

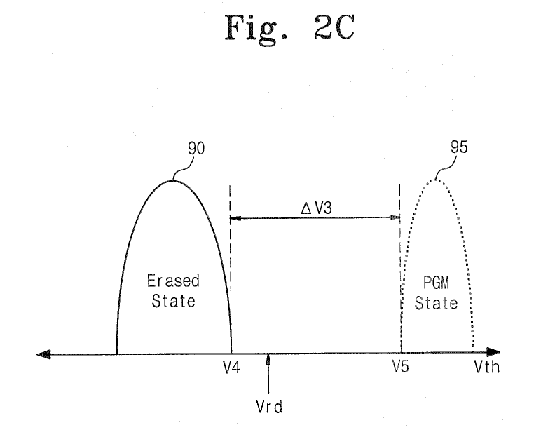

FIG. 3 is a block diagram of a memory system according to an exemplary embodiment of the present invention;

FIG. 4 is a block diagram of a data structure in a contents memory of the system shown in FIG. 3;

FIG. 5 is a flowchart illustrating an access method of a flash memory system;

FIGS. 6A, 6B, and 6C are graphs illustrating program conditions according to an exemplary embodiment of the present invention; and

FIG. 7 is a graph of read conditions according to an exemplary embodiment of the present invention.

### DETAILED DESCRIPTION OF EXEMPLARY EMBODIMENTS

The above general description and the following detailed description are exemplary to provide additional reference of the present invention. In any case, like reference numerals used in the drawings refer to like elements throughout.

Hereinafter, a NAND flash memory device is used to explain features and functions of exemplary embodiments of the present invention. Those will ordinary skill in the art, however, will easily understand other advantages and performances of the present invention according to the following descriptions. The present invention also can be embodied or applied through other exemplary embodiments. The above-disclosed subject matter is to be considered illustrative, and not restrictive, and the appended claims are intended to cover all such modifications, enhancements, and other exemplary embodiments, which fall within the true spirit and scope of the present invention.

Hereinafter, will be described an exemplary embodiment of the present invention in conjunction with the accompanying drawings.

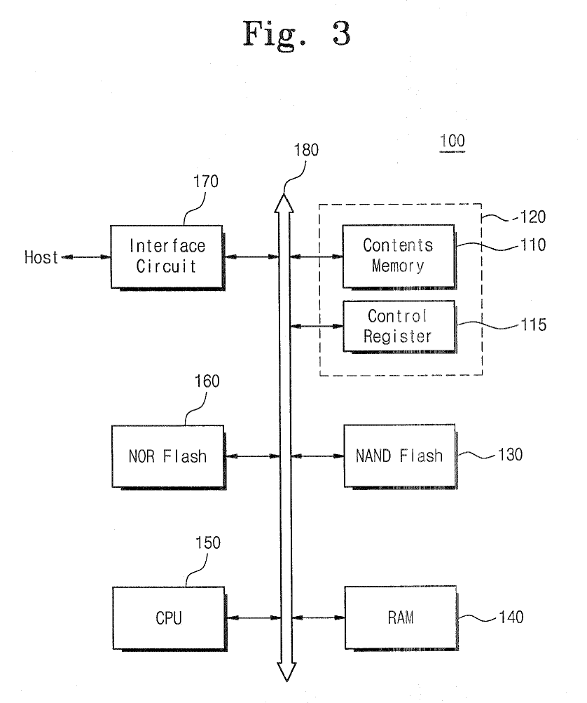

FIG. 3 is a block diagram of a memory system 100 according to an exemplary embodiment of the present invention. Referring to FIG. 3, the system 100 includes a contents memory 110 storing setting information corresponding to a specific memory region (for example, a page unit) of a NAND flash memory 130. The system 100 may include a smart card or other module device, for example.

The contents memory 110 is electrically connected to a system bus 180, and stores setting information corresponding to the NAND flash memory 130. More specifically, the contents memory 110 stores the setting information corresponding to each page in the NAND flash memory 130. The setting information includes at least one of a program parameter, a read parameter, and an erase parameter for each page in the NAND flash memory 130. Access for the NAND flash memory 130 is performed according to the setting information corresponding to each of the pages. The contents memory 110 may be formed of a non-volatile memory device that can retain its data regardless of the presence of a power supply. More specifically, the contents memory 110 should be formed of a programmable non-volatile memory device for continuously updating the setting information.

A control register 115 temporarily stores the setting information, and the stored setting information is provided to a processing unit 150, such as a central processing unit (CPU), that accesses the NAND flash memory 130. The control register 115 stores setting information for a page corresponding to a command and an address that are provided by the processing unit 150. The contents memory 110 and the control register 115 constitute a setting information supplying unit 120 that provides the setting information for the corresponding address to the processing unit 150. It will be apparent to those of ordinary skill in the art that the operation of the control register 115 can be performed in a RAM 140. The control register 115 is electrically connected to the system bus 180.

The NAND flash memory 130 includes highly integrated flash memory cells. More specifically, in an embedded environment, the NAND flash memory 130 often shares a high voltage with a NOR flash memory 160. For programming a memory cell, a negative high voltage (approximately −6 V) is applied to a bulk region of the NAND flash memory 130. Since a 10 V high voltage is applied to a select word line, the memory cell is programmed by F-N tunneling. In the embedded environment, the NAND flash memory 130 may be directly connected to the system bus 180 without using an interface, such as a flash interface. For example, a flash translation layer (FTL) that is typically controlled by a flash interface can be controlled by the already-equipped processing unit 150. In the embedded environment, the NAND flash memory 130 may receive addresses, control signals, and data, separately.

The RAM 140 is electrically connected to the system bus 180, and is used as an operation memory of the system 100. The boot codes or other application programs in the NOR flash memory 160 are loaded into the RAM 140 when the system is booted. The RAM 140 may load the setting information read from the contents memory 110 instead of the control register 115. While accessing the NAND flash memory 130, the setting information in the RAM 140 is used by the processing unit 150.

The processing unit 150 performs general control operations of the system by the boot code or operating system (OS) that are loaded into the RAM 140. In the embedded environment, the processing unit 150 directly controls program, read, and erase operations of the NAND flash memory 130. That is, the processing unit 150 performs the general control operations of the flash interface in the NAND flash memory 130.

A NOR flash memory 160 is electrically connected to the system bus 180, and stores code data or other programs that are executed by the processing unit 150. The interface circuit 170 controls a data exchange between the system 100 and the host (not shown).

As illustrated in FIG. 3, the system 100 includes the NAND flash memory 130 and the contents memory 110 storing setting information in a page unit or a block unit of the NAND flash memory 130. An access operation for the NAND flash memory 130 by the processing unit 150 is performed on the basis of the setting information. The NAND flash memory 130 performs program, read, and erase operations by considering operational characteristics that are subdivided into a page unit. Accordingly, the system of the present invention can provide a high-speed and reliable access operation for the NAND flash memory 130.

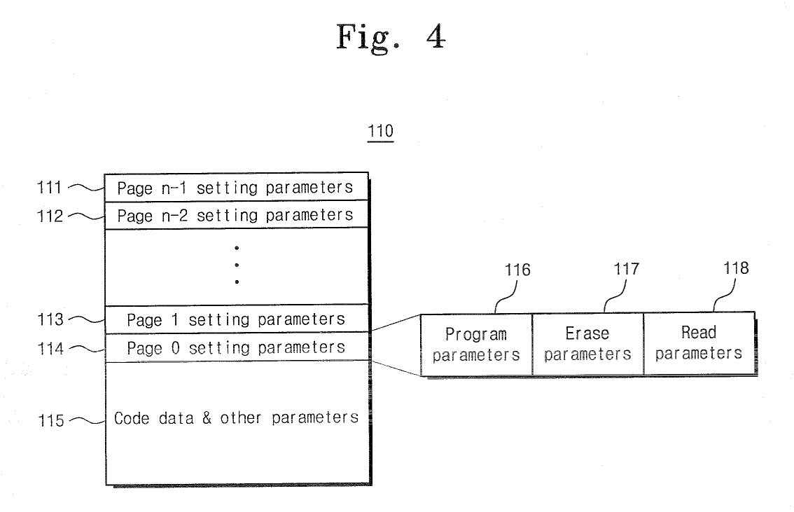

FIG. 4 is a block diagram of a data structure in the contents memory 110 of FIG. 3. Referring to FIG. 4, the contents memory 110 stores setting information for each of the pages constituting the NAND flash memory 130. The setting information for each of the pages is stored in storage regions 111 to 114. When there are the total n number of pages in the NAND flash memory 130, the contents memory 110 stores respective setting information for the n number of pages.

For example, a region 114 storing the setting information for a page 0 includes blocks 116 to 118. The setting information corresponding to the Page 0 setting parameters includes program parameters 116 necessary for a program operation. The setting information corresponding to the Page 0 setting parameters further includes erase parameters 117 and read parameters 118.

The program parameters 116 include general information necessary for a program operation of the NAND flash memory. For example, a program start voltage (when applying an ISPP) of a corresponding page, the step size of the program pulse, and the number of loops consumed for the program are included in the program parameters 116. The program parameters 116 may include verify voltages for an optimized program verification besides the above conditions.

The erase parameters 117 include an erase voltage of a corresponding memory region. For example, the erase parameters 117 may include an erase verify voltage. The erase parameters 117 may include a voltage applied to a bulk region during an erase operation or an applying time of the erase voltage. In an advanced technology, it is apparent to those of ordinary skill in the art that a word line voltage applied to each word line may be included in the erase parameters 117 as soon as a high voltage is applied to a bulk of the memory block.

The read parameters 118 include read voltages optimized for a corresponding page. The read parameters 118 include a voltage capable of providing the maximum read margin into the threshold voltage distribution of the memory cells in the corresponding page.

The contents memory 110 also stores the code data 115 of the NAND flash memory 130 and other parameters.

As illustrated in FIG. 4, the contents memory 110 stores the setting information corresponding to each page of the NAND flash memory 130. It is apparent to those or ordinary skill in the art, however, that the setting information can store access data for each page unit, or access data for a memory region unit that is larger or smaller than the page unit. For example, the setting information can be stored by a sector unit or a block unit.

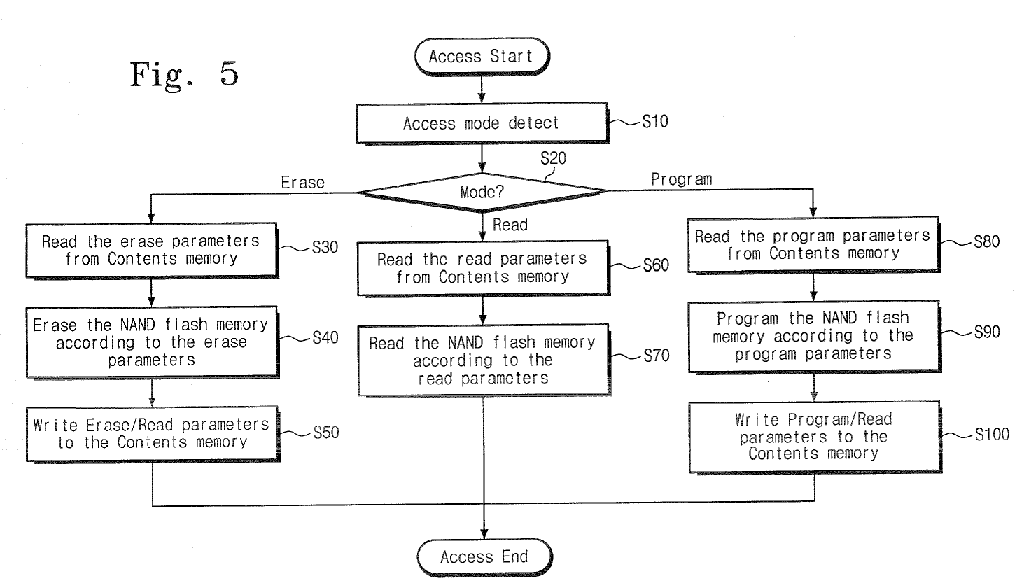

FIG. 5 is a flowchart illustrating an access operation for a flash memory system 130, which is executed by the processing unit 150. Referring to FIG. 5, according to each operational mode (erase, read, and program), the processing unit 150 reads corresponding parameters stored in the contents memory 110. Based on the read parameters, the processing unit 150 accesses the NAND flash memory 130.

Once an access operation begins, the processing unit 150 detects a command and an address that are provided to the NAND flash memory 130 in operation S10. In operation S20, the processing unit 150 detects the command to determine which operation is to be performed. When determining an erase operational mode, the processing unit 150 accesses the contents memory 110 to read an erase parameter of a page corresponding to the corresponding address. The read erase parameter is stored in a control register 115 or a RAM 140 in operation S30. The processing unit 150 calculates an optimized erase voltage and an erase timing based on the read erase parameter. The processing unit 150 controls the NAND flash memory 130 to erase the memory region selected under the optimized voltage and time conditions in operation S40. When an erase operation is completed, the processing unit 150 reprograms the erase parameter and read parameter of a corresponding memory region in the contents memory 110. The erase operation, the erase parameter and the read parameter that are reprogrammed in the contents memory 110 are parameters that are optimized values according to operations of the processing unit in operation S50.

When the detected operation mode is a read mode, the processing unit 150 reads the read parameters of the page or pages corresponding to the address from the contents memory 110 in operation S60. The processing unit 150 accesses the NAND flash memory by using the read parameter and reads the data corresponding to the address. The read parameter is the optimized read voltages corresponding to the corresponding page. In the case of a multi-bit memory storing a plurality of data in one memory cell, the memory cell is programmed by using one in a plurality of threshold voltage states corresponding to multi-bit data, respectively. Accordingly, the read voltage corresponding to one page is determined by the number of threshold voltage distributions in operation S70. The read operational mode does not need to include an update operation of the read parameter. The reason for this is that the read parameter is updated to the optimized value in the program mode or the erase mode.

When the detected operation mode is a program mode, the processing unit 150 reads program parameter of a corresponding page or pages from the contents memory 110. The read program parameter is stored in the control register 115 or the RAM 140 in operation S80. The processing unit 150 sets up the optimized program start voltage, the number of program loops, the step size of the program pulse, and a verify voltage based on the read program parameter. The processing unit 150 control the NAND flash memory 130 to program pages selected according to the optimized voltages for programming a corresponding page in operation S90. When a program operation for a page corresponding to an address is completed, the processing unit 150 updates a program parameter of a corresponding memory region and a read parameter in the contents memory 110. Here, the updated program parameter and the read parameter are calculated using the optimized values by the processing unit 150, and then are programmed in the contents memory in operation S100.

According to an access method for the NAND flash memory including the contents memory 110 that provides parameters corresponding to each operational mode, the optimized access parameter is always provided. Accordingly, the access speed increases, and also an embedded system having a high reliability can be achieved.

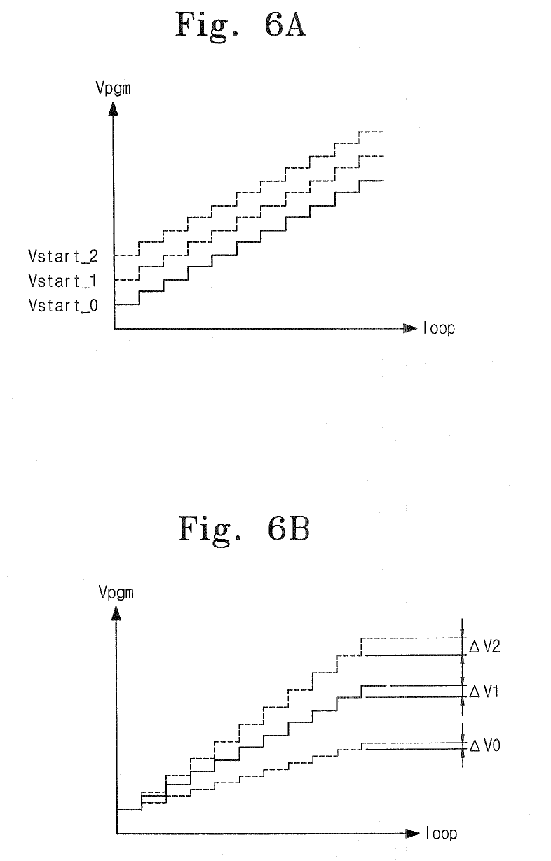

FIGS. 6A, 6B, and 6C are graphs illustrating program conditions according to an exemplary embodiment of the present invention. Referring to FIG. 6A, a program start voltage can be provided into each page with an optimized size. The various step sizes of the program voltage for the program operation can be provided as illustrated in FIG. 6B. In the program parameter stored in the contents memory 110, there is a parameter for selecting the step size of the program voltage. From among a plurality of step sizes ΔV0, ΔV1, and ΔV2, the optimized step for a corresponding page is selected and then is stored in the contents memory 110. FIG. 6C illustrates the number of program loops as a program parameter of the selected page. The number of program loops optimized for program speed of the memory cells can be selected as the program parameter.

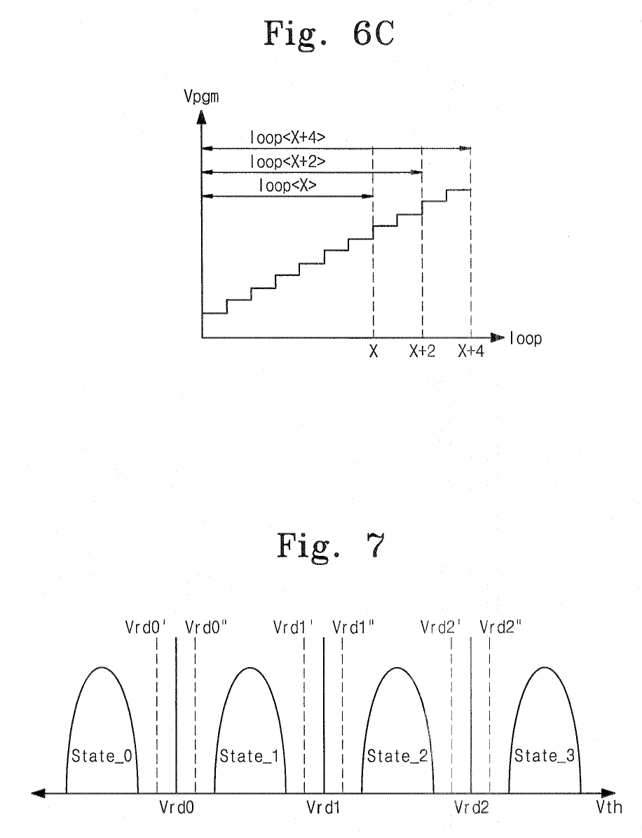

FIG. 7 is a graph of read conditions according to an exemplary embodiment of the present invention. Referring to FIG. 7, a read voltage Vrd is selected as an optimized voltage for threshold voltage distribution of the memory cells in the page unit. The read parameter is programmed into the contents memory 110 to select the optimized read voltage. In FIG. 7, the read voltage can be selected from among three voltages VRd0, VRd0′, and VRd0″. It is apparent to those of ordinary skill in the art that the kinds of the read voltages can be more than three.

The NAND flash memory of the exemplary embodiments of the present invention uses an embedded NAND flash memory, which performs a program operation under the high voltage conditions that can be shared with a NOR flash memory. The present invention, however, is not limited to the embedded NAND flash memory. It is apparent to those of ordinary skill in the art that the present invention can be applied to all semiconductor memory devices to which a program method of the present invention can be applied.

According to exemplary embodiments of the present invention, since the access parameter can be provided by the minimum access unit, and can be continuously updated, a high-speed and reliable embedded flash memory system can be achieved.

The above-disclosed subject matter is to be considered illustrative, and not restrictive, and the appended claims are intended to cover all such modifications, enhancements, and other exemplary embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A system comprising:
a flash memory device including a plurality of storage regions;
a contents memory storing setting information corresponding to the plurality of storage regions, respectively; and
a processing unit setting operation conditions of the flash memory device by referring to the setting information during an access operation for the flash memory device.

2. The system of claim 1, wherein the flash memory device is a NAND flash memory.

3. The system of claim 2, wherein the plurality of storage regions is in page units.

4. The system of claim 3, wherein the setting information comprises one of a program parameter, an erase parameter, and a read parameter for one page unit.

5. The system of claim 4, wherein the program parameter comprises one of information such as a program start voltage, a step width, a level of a program voltage, and a number of program loops for one page unit.

6. The system of claim 4, wherein the erase parameter comprises a size of a bulk voltage that is applied when an erase operation is performed.

7. The system of claim 4, wherein the read parameter comprises a size of a word line voltage that is applied when a read operation is performed.

8. The system of claim 1, wherein the contents memory is a non-volatile memory.

9. The system of claim 8, wherein the processing unit detects a mode of the access operation and reads the setting information corresponding to the detected mode from the contents memory.

10. The system of claim 9, wherein the processing unit performs a control operation for performing one of a read operation and a write operation by referring to the setting information.

11. The system of claim 10, wherein the processing unit updates the setting information in the contents memory after the access operation.

12. The system of claim 1, further comprising a control register temporarily storing the setting information read from the contents memory.

13. The system of claim 12, wherein the setting information are parameters corresponding to at least one storage region in the plurality of storage regions, the at least one storage region being accessed during the access operation.

14. The system of claim 1, wherein the flash memory device, the contents memory, and the processing unit are embedded devices and are embedded on a single chip.

15. An access method for a flash memory device including a plurality of storage regions, the method comprising:
detecting an access mode;
reading setting information corresponding to the access mode; and
setting operation conditions of the flash memory device according to the setting information.

16. The method of claim 15, wherein the access mode is a program operation mode writing data into the flash memory device.

17. The method of claim 16, wherein the setting information corresponding to the program operation mode comprises at least one of information such as a program start voltage, a step size of a program pulse, a number of program loops, and a size of a verify voltage.

18. The method of claim 15, wherein the access mode is a read operation mode reading data programmed in the flash memory device.

19. The method of claim 18, wherein the setting information corresponding to the read operation mode comprises information of a voltage supplied to a selected word line during the reading of the programmed data.

20. The method of claim 15, wherein the access mode is an erase operation mode erasing data programmed in the flash memory device.

21. The method of claim 20, wherein the setting information corresponding to the erase operation mode comprises at least one of bulk voltage information applied during the erase operation and size information of a word line voltage.

22. The method of claim 15, further comprising accessing the flash memory device according to the access mode when the setting of the operation conditions is completed in the flash memory device.

23. The method of claim 22, further comprising updating the setting information according to the accessing operation.

24. The method of claim 15, wherein the setting information is stored in non-volatile memory separated from the flash memory device.

25. The method of claim 15, wherein the flash memory device is a NAND flash memory.

26. The method of claim 25, wherein the plurality of storage regions correspond to a page unit.

27. The method of claim 25, wherein the plurality of storage regions correspond to a block unit.

28. The method of claim 15, wherein the flash memory device is an embedded NAND flash memory device.

29. A system comprising:
a flash memory device including a plurality of storage regions;
a processing unit setting operation conditions of the flash memory device by referring to the setting information corresponding to the respective plurality of storage regions during an access operation for the flash memory device.

30. The system of claim 29, wherein the setting information corresponding to the plurality of storage regions is stored in the contents memory.
